(19) United States
(12) Patent Application Publication
(10) Pub. No.: US 2014/0102358 A1
(43) Pub. Date: Apr. 17, 2014

(54) METHOD, DIE, AND APPARATUS FOR CRYSTAL GROWTH

(71) Applicants: Jan J. Buzniak, Solon, OH (US); Naveen Tiwari, Shrewsbury, MA (US); Vignesh Rajamani, Wilmington, MA (US); Charles Gasdaska, Shrewsbury, MA (US); Christopher D. Jones, Amherst, NH (US); Guilford L. Mack, III, Manchester, NH (US); Fery Pranadi, Nashua, NH (US); Maureen DeLoffi, Mansfield, MA (US); Martin Z. Bazant, Lexington, MA (US)

(72) Inventors: Jan J. Buzniak, Solon, OH (US); Naveen Tiwari, Shrewsbury, MA (US); Vignesh Rajamani, Wilmington, MA (US); Charles Gasdaska, Shrewsbury, MA (US); Christopher D. Jones, Amherst, NH (US); Guilford L. Mack, III, Manchester, NH (US); Fery Pranadi, Nashua, NH (US); Maureen DeLoffi, Mansfield, MA (US); Martin Z. Bazant, Lexington, MA (US)

(21) Appl. No.: 14/041,592

(22) Filed: Sep. 30, 2013

Related U.S. Application Data
(60) Provisional application No. 61/708,032, filed on Sep. 30, 2012.

(51) Int. Cl. C30B 15/34

(52) U.S. Cl. CPC C30B 15/34
USPC 117/26; 117/211

(57) ABSTRACT

An apparatus, die, and method can be used form a ribbon from a melt, where capillaries are relatively short and spacers are relatively long as compared to a die opening. Such a configuration can cause the melt to flow is a transverse direction that is substantially parallel to the solid/liquid interface to help move impurities to desired locations. In a particular embodiment, a crystal ribbon can be formed where defects, such as microvoids and impurities, are at higher concentrations near outer edges of the crystal ribbon. The outer edges can be removed to produce crystal substrates that are substantially free of microvoids and have no or a relatively low concentration of impurities. In another particular embodiment, the transverse flow can also help to increase the crystal growth rate.

### CROSS-REFERENCE TO RELATED APPLICATION

This application claims priority under 35 U.S.C. §119(e) to U.S. Patent Application No. 61/708,032 entitled “Method and Apparatus for Crystal Growth” by Buzniak et al. filed Sep. 30, 2012, which is assigned to the current assignee hereof and incorporated herein by reference in its entirety.

### FIELD OF THE DISCLOSURE

This disclosure, in general, relates to apparatuses, dies, and methods of growing crystals from a melt.

### BACKGROUND

Sapphire is an important material used in semiconductor device technology. Sapphire substrates offer a number of advantages that make them widely used in a number of specialized applications where silicone substrates are not appropriate. For example, sapphire substrates are the most commonly used substrates for thin film GaN-based LEDs, which are poised to replace incandescent and fluorescent lights in many applications.

Unfortunately, sapphire crystals, especially large sapphire ribbons suitable for cutting into 6-inch sapphire substrates typically contain a number of characteristic defects such as microvoids. These microvoids have negative effects on a number of applications for sapphire crystals. The number and distribution of microvoids during the crystal growth process is thought to be affected by impurities in the aluminum oxide (Al₂O₃) melt from which the sapphire crystals are grown. Crystal quality can be improved by removing impurities from the aluminum oxide, but it is impossible to remove all impurities. The presence of microvoid defects can also be limited by increasing the temperature gradient in the growth direction. However, it can be difficult to accurately control and sustain sufficiently large temperature gradients near the crystal melt solidification front, which leads undesirably to a fundamental growth rate limitation.

Because defects, such as microvoids and impurities, tend to concentrate along the external faces of the crystal, for reasons which are not entirely understood, such defects are removed by polishing or grinding away the entire outer surface of a crystal. Such a process is not only time consuming and expensive, but it also serves to waste a large amount of the crystal material and limits the size of relatively microvoid-free sapphire substrates that can be produced that are substantially free of microvoids and higher concentrations of impurities.

### BRIEF DESCRIPTION OF THE DRAWINGS

The present disclosure may be better understood, and its numerous features and advantages made apparent to those skilled in the art by referencing the accompanying drawings.

FIG. 1 includes an illustration of a prior art EFG growth apparatus.

FIG. 2 includes an illustration of a prior art die used to form a crystal ribbon.

FIG. 3 includes an illustration of a top view of a die having a die opening in accordance with a particular embodiment.

FIG. 4 includes an illustration of a cross-sectional view of the die at sectioning line 4-4 in FIG. 3.

FIG. 5 includes an illustration of a die plate according to the particular embodiment.

FIG. 6 includes an illustration of a cross-sectional view of the die at sectioning line 6-6 in FIG. 3.

FIG. 7 includes an illustration of a top view of a die having a die opening in accordance with another particular embodiment.

FIG. 8 includes an illustration an enlarged view of the restricting channel for one of the spacers from FIG. 6.

FIG. 9 includes an illustration of an enlarged view of the sloping top surface of the spacer illustrated in the dashed line box in FIG. 8.

FIG. 10 includes an illustration of another spacer design according to a particular embodiment.

FIG. 11 includes an illustration of a flowchart of an exemplary method of growing a crystal ribbon according to a particular embodiment.

FIG. 12 includes a photograph of actual crystal ribbons grown according to a particular embodiment.

The accompanying drawings are not intended to be drawn to scale. In the drawings, each identical or nearly identical component that is illustrated in various figures is represented by a like numeral. For purposes of clarity, not every component may be labeled in every drawing.

### DETAILED DESCRIPTION

A transverse flow, which is parallel to a solid/liquid interface, of a melt within a die tip channel adjacent to the solid/liquid interface can be used to help to move defects, such as microvoids and impurities, in the direction of the transverse flow. Thus, the locations of such defects in a body, such as a crystal, formed from the melt can be controlled. For example, a transverse flow toward the outer edges of a die tip channel allows the defects to be concentrated more heavily along the outer edges of the crystal, where they can be more readily removed to leave behind a remaining portion of the crystal that is substantially free of defects, such as microvoids and impurities at relatively higher concentrations. Also, by lowering the impurity concentration at the solid/liquid interface, constitutional supercooling is reduced, thus lowering the maximum G/R ratio and enabling faster growth, with fewer defects. The desired transverse melt flow can be achieved by restricted melt flow at one or more particular regions within the die tip cavity, gravity driven flow, or a combination thereof, as described in greater detail below.

Before addressing details in the embodiments below, terms are defined to improve understanding of the concepts as described herein. The term “ribbon” refers to a sheet of material that is formed using a shaped body growth technique. When forming a crystal ribbon using a die, the die has a die opening that corresponds to the shape of the crystal ribbon formed using the die. As seen from a top view, the die opening has a length and a width that is smaller than the length. When referring to features within the die opening, lengths of such features measured in a direction parallel to the length of the die opening, and widths of such features are measured in a direction parallel to the width of the opening.

When forming the crystal ribbon, the length of the die opening corresponds to the width of the crystal ribbon, and the width of the die opening corresponds to the thickness of the crystal ribbon. The length of the crystal ribbon is measured in a direction perpendicular to the width and thickness of the crystal ribbon. The crystal ribbon has major surfaces along opposite sides of the crystal ribbon, wherein the major surfaces corresponding to the length of the die opening. The major surfaces may correspond to the A-plane, C-plane, M-plane, or R-plane, and thus, the major surfaces may be at or within a few degrees of one of such planes. Outer edges of the crystal ribbon are along opposite sides between the major surfaces and correspond to the width of the die opening.

As used herein, the terms “comprises,” “comprising,” “includes,” “including,” “has,” “having,” or any other variation thereof, are intended to cover a non-exclusive inclusion. For example, a process, method, article, or apparatus that comprises a list of features is not necessarily limited only to those features but may include other features not expressly listed or inherent to such process, method, article, or apparatus. Further, unless expressly stated to the contrary, “or” refers to an inclusive-or and not to an exclusive-or. For example, a condition A or B is satisfied by any one of the following: A is true (or present) and B is false (or not present), A is false (or not present) and B is true (or present), and both A and B are true (or present).

The use of “a” or “an” is employed to describe elements and components described herein. This is done merely for convenience and to give a general sense of the scope of the invention. This description should be read to include one or at least one and the singular also includes the plural, or vice versa, unless it is clear that it is meant otherwise.

Unless otherwise defined, all technical and scientific terms used herein have the same meaning as commonly understood by one of ordinary skill in the art to which this invention belongs. The materials, methods, and examples are illustrative only and not intended to be limiting. To the extent not described herein, many details regarding specific materials and processing acts are conventional and may be found in textbooks and other sources within the crystal and crystal growth arts.

Embodiments as described herein are primarily directed at growing wide and thin crystal ribbons. Typically, crystal ribbons can be used to prepare single crystal substrates that can be over 15 cm (6 inches) wide and from 0.25 cm to 1.25 cm (0.10 to 0.50 inches) in thickness. For sapphire, nominal widths can include 15 cm (6 inches), 18 cm (7 inches), 20 cm (8 inches), 25 cm (10 inches), 30 cm (12 inches) or even wider. The actual width achieved by depend in part of the orientation of the crystal with respect to the primary surfaces, control of temperature gradients along the length of the die, in a direction of crystal growth, or the like. Embodiments include methods, dies, and apparatuses to allow faster growth rates for such crystal ribbons, while reducing the undesirable effects caused by the appearance of microvoid defects within the crystalline material. In a particular embodiment, crystals can be grown using Edge-Defined, Film-Fed Growth (EFG).

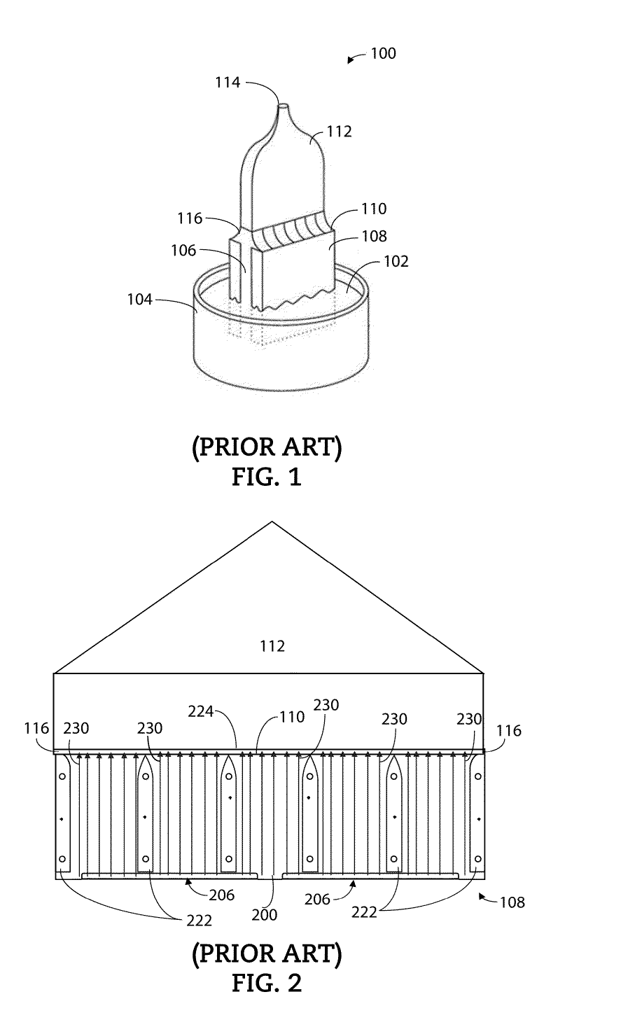

Before addressing embodiments in accordance with the concepts described herein, a typical prior art EFG growth is illustrated and described. In the prior art EFG process using an apparatus 100 in FIG. 1, a crystal is grown from a melted feed material 102 that is transported by capillary action from a crucible 104 and up through one or more capillaries 106 in a die 108 to the upper die surface 110 of the die 108. The shape of a crystal ribbon 112 formed by the die 108 is determined by the external or edge configuration of the top surface of the die opening. A seed crystal 114 is brought into contact with a thin layer of melt exposed within die opening (commonly referred to as the meniscus 116) on the die tip 110 and then withdrawn. As the seed is withdrawn, the melt material crystallizes onto the seed.

A typical die used to form the crystal ribbon 112 is illustrated in FIG. 2. In FIG. 2, the die 108 is illustrated without the front die plate so that the arrangement of spacers 222 and the melt flow through the die 108 can be seen. The die 108 includes two adjacent rectangular die plates 200, separated by spacers 222 so that the die plates 200 are only separated by a small distance, typically from 0.25 cm to 1.25 cm (0.10 to 0.5 inches), which corresponds to the width of the die opening and the thickness of the crystal ribbon. As can be seen in FIG. 2, only a small fraction of the length (horizontal direction in FIG. 2) of the die opening is occupied by the spacers 222. This arrangement results in a number of relatively long capillaries 206 between the spacers 222 through which the melt flows from the crucible to the upper surface 110 of the die tip. The melt then flows to the die tips to form a thin wetting layer of melted material (the meniscus 116) having boundaries at the outer edges of the die tips. The crystal growth occurs at the solid/liquid interface 224 at the upper surface of the thin wetting layer of melted material, with the resulting crystal ribbon 112 having a width and thickness that is approximately the same as the length and width of the die opening. Thus, the width of the crystal ribbon is approximately equal to the length of the die plates 200, and the thickness of the crystal ribbon is approximately equal to the width of the spacers 222.

In the die of FIG. 2, the great majority of the melt flow will be straight up between the spacers 222 as illustrated by arrows 230 (indicating the direction of flow). Only a very small amount of flow will be in a direction parallel to the solid/liquid interface, in order to cover the tops of the spacers 222 and with some transverse flow moving from the inner edge of the die plates 200 to the outer face of the plates 200 (so that the top edges of the die plates are covered by the meniscus). As illustrated in FIG. 2, the total length of the spacers 222 is only a very small portion of the length of the die opening (typically less than 20%). The remainder of the length of the die opening corresponds to capillaries 206 that allow melt flow vertically, and thus, the majority of the flow near the solid/liquid interface is perpendicular to the solid/liquid interface.

As described above, many types of crystals, especially sapphire crystals, grown using these types of prior art dies typically contain a number of characteristic defects, such as microvoids and locally higher impurity concentrations. Such defects, such as microvoids and impurities, tend to concentrate more along the external faces of the crystal, which include the primary surfaces and outer edges, as compared to internally within the crystal, for reasons which are not entirely understood. Typically, such defects are removed by polishing or grinding away the entire outer surface of a crystal, which includes the primary surfaces. Such a process is not only time consuming and expensive, but it also serves to waste a large amount of the crystal material and limits the size of crystal substrates that can be produced substantially free of such defects.

The number and distribution of microvoids during the crystal growth process is thought to be affected by impurities in the feed stock from which the crystals are grown. Crystal quality can be improved by removing impurities from the feed stock, but it is impossible to remove all impurities. If the impurities are at a high enough concentration, the microvoids can make the crystal unusable. Further, because the impurities in the feed stock are at levels typically in a range of 30-50 ppm and because the difference between a feed stock with an acceptable concentration of impurities and unacceptable feed stock is so small, possibly only a few ppm, it is very difficult to determine whether a feed material will be acceptable by any method other than using it to grow crystals. This results in a great deal of waste, both in the purchase of unacceptable feed stocks and in the time and expense of growing unusable crystals.

Impurities at the solid/liquid interface also lead to a growth rate limitation for crystal growth. The presence of impurities at the growth interface can cause problems due to impurity segregation and constitutional supercooling. Although these problems can be addressed by increasing temperature gradient G along the growth direction (relative to the growth rate R), it can be difficult to accurately control and sustain sufficiently large temperature gradients near the solidification front.

Embodiments as described herein, however, make it possible to use feed stocks with levels of impurities that would be unacceptable using prior art dies and methods. Impurities can be moved to the outer edges of the die tip channel, rather than distributed across the solidification front. As a result, defects in the resulting crystal body will be concentrated more along the outer edges of the crystal and not along substantially all of the primary surfaces, which allows a crystal ribbon substantially free of microvoids to be produced more easily by removing portions along the outer edges of the ribbon. Also, by lowering the impurity concentration at the solid/liquid interface, constitutional supercooling is reduced, thus lowering the maximum G/R ratio and enabling faster crystal growth.

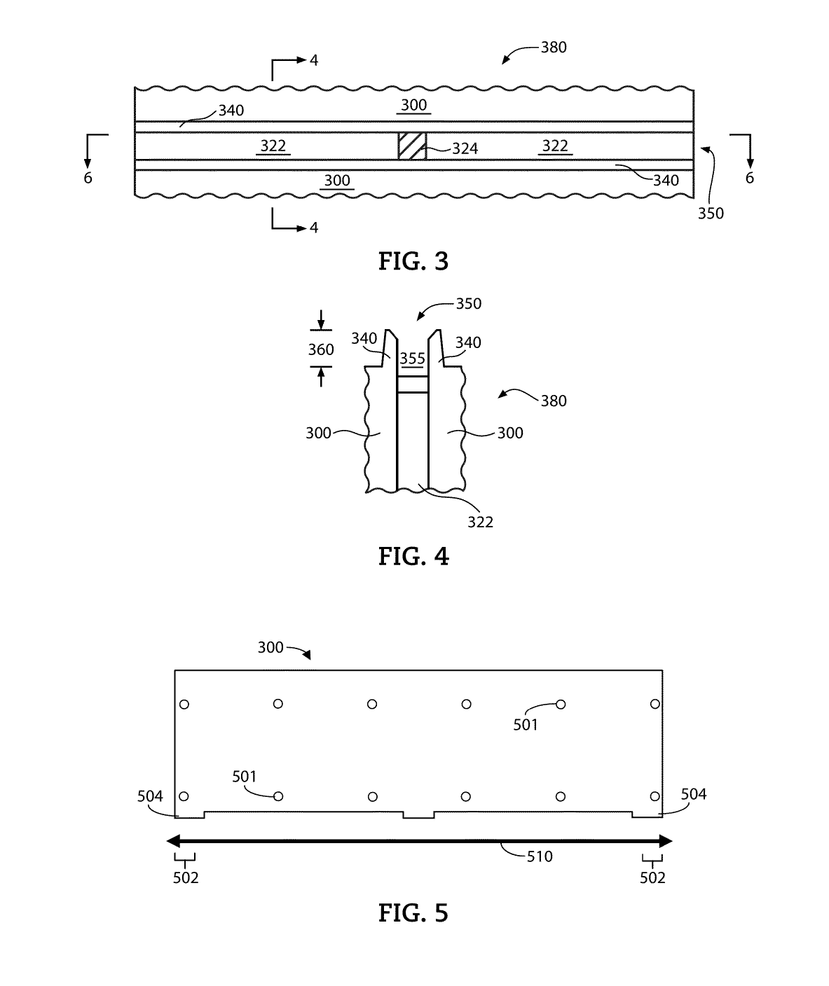

According to a particular embodiment, an apparatus is configured to grow a crystal, such as a crystal ribbon. A die to control the shape of the crystal growth can include at least two generally rectangular plates. For example, suitable die plates could be approximately 15 cm (6 inches) wide, 5 cm (2 inches) tall, and 0.25 cm (0.10 inches) thick. In other embodiments, other sizes of die plates can be used to achieve other sizes of crystal ribbons. FIGS. 3 to 6 include illustrations of an exemplary, non-limiting embodiment to illustrate features of a particular die that can be used in accordance with the concepts as described herein.

FIG. 3 includes an illustration of a top view a die 380 that includes die plates 300 that are separated by spacers 322, and FIG. 4 is a cross-sectional view of the die 380 at sectioning line 4-4 in FIG. 3. The die 380 has a die opening 350 having a length extending from the vertical line at the left-hand side of FIG. 3 to the vertical line at the right-hand side of FIG. 3. A capillary 324 is disposed between the spacers 322. The length of the capillary 324, which is measured in the same direction of as the length of the die opening 350, is a small fraction of the length of the die opening 350. The spacers 322 occupy the remainder of the length of the die opening 350. The width of the capillary 324 is the same as the thickness of the spacers 322. The die plates 300 include die tips 340, which in the embodiment as illustrated in FIG. 4, are sloped toward the die opening 350. As illustrated, the die tips 340 have a sloped surface that is substantially planar. In another embodiment, the die tips 340 have a curved surface (for example, convex or concave) or have a substantially flat surface along a horizontal plane. Thus, from a cross-sectional view along a width of the die as illustrated in FIG. 4, the die tips can be rectangular, sloped, or curved.

A die tip channel 355 includes the die opening 350, wherein the die tip channel 355 has a bottom that corresponds to the upper surfaces of the spacers 322, sides that are corresponding to the die plates 300, and extends to the uppermost points of die tips 340. An elevational difference 360 between the uppermost points of the die tips 340 and uppermost points of the spacers 322 can be at least 0.11 cm (0.043 inches), at least 0.13 cm (0.05 inches), or is at least 0.19 cm (0.075 inches).

FIG. 5 includes an illustration of one of the die plates 300. Rivet holes 501 are used to join the die plates 300 and spacers 322 together. Feet 504 are used to support the die plate 300 within the crucible while maintaining a spacing between the crucible floor and the bottom of the die plate 300 at locations away from the feet 504 so that a melt can enter the die 380 from the bottom and be drawn up to the die tip channel 355 via capillary action. In this embodiment, the length 510 of the die opening 350 is substantially the same as the length of the die plates 300. The outer edge regions 502 correspond to outer edges of the crystal ribbon where defects, such as microvoids and locally higher impurity concentrations, will be formed.

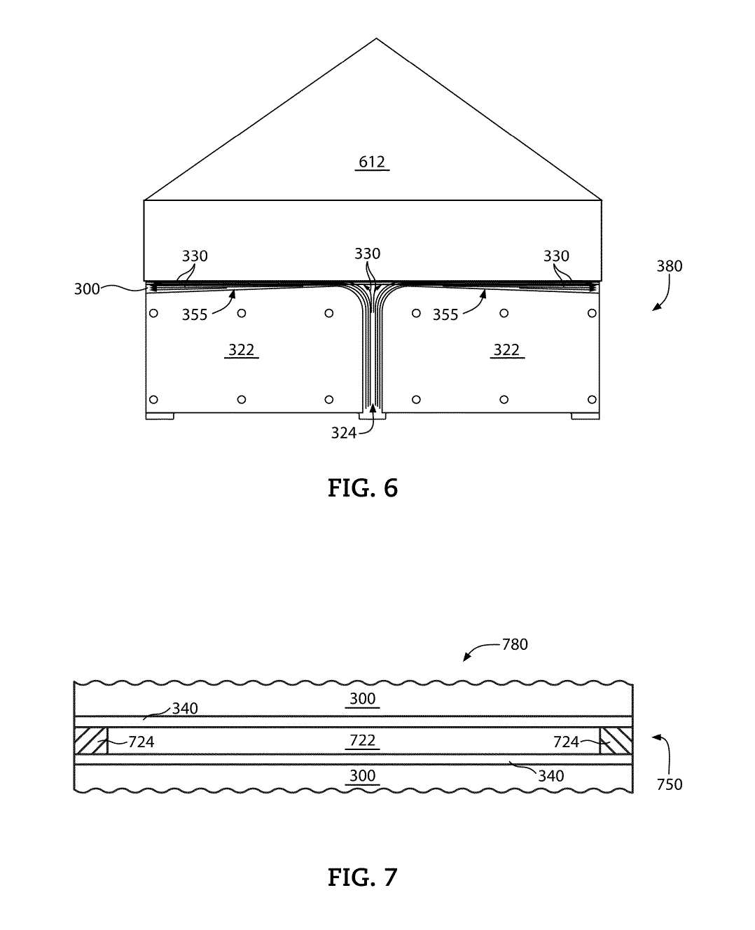

FIG. 6 includes an illustration of the die 380 at sectioning line 6-6 in FIG. 3 during the formation of a crystal ribbon 612. FIG. 6 illustrates the flow of the melt though the capillary 324 and within the die tip channel 355 during crystal growth. As the crystal ribbon 612 is formed, capillary action draws the melt up the capillary 324 and into the die tip channel 355 outward away from the capillary 324, as generally illustrated by arrows 330 in FIG. 6.

This restriction in the vertical flow of the melt to the capillary 324, which is a relatively small percentage of the length of the die plates 300, results in a much larger velocity for the transverse flow (in a direction parallel to the solid/liquid interface) of the melt within the die tip channel 355, as compared to the velocity of the melt flowing up within the capillary 324. More particularly, when the melt reaches the top of the capillary 324, the melt flows over the upper surfaces of the spacers 322 within the die tip channel 355, resulting in a large transverse flow out toward both outer edges of the die tip channel 355 and the die opening 350. The velocity of the melt flowing within the die tip channel 355 adjacent to the capillary 324 is higher than (1) the velocity of the melt flowing up the capillary 324 and (2) the velocity of the melt flowing within the die tip channel 355 farther from the capillary 324. In this embodiment, defects, such as microvoids and impurities, can be more concentrated within the portions of the crystal ribbon 612 closer to the outer edges, as compared to the primary surfaces of the crystal ribbon 612 formed near the center of the die opening 350.

In other embodiments, the defects can be concentrated at one or more in different locations, as needed or desired. In another embodiment, a single capillary can be located within the die in a position other than at the exact center of the die opening. In a particular embodiment, defects, such as microvoids and impurities, can be concentrated at locations other than the outer edges of the crystal. FIG. 7 includes an illustration of another embodiment having more than one capillary. A spacer 722 is positioned between the die plates 300. In this embodiment, capillaries 724 are located at opposite ends of the die opening 750. When the melt reaches the top of the capillaries 724, the melt flows within the die tip channel over the upper surface of the spacer 722, resulting in a large transverse flow from both outer edges of the die opening 750 towards the center of the die opening 750. The velocities of the melt flowing within the die tip channel adjacent to the capillaries 724 are higher than (1) the velocity of the melt flowing up the capillaries 724 and (2) the velocity of the melt flowing within the die tip channel closer to the center of the die opening 750. In this embodiment, defects from impurities and microvoids will be more concentrated within the portions of the crystal ribbon closer to the center of the die opening 750 as compared to the outer edges. Thus, the defects may be more concentrated within a central band of the crystal ribbon, as compared to the outer edges. In other embodiments, a different number or configuration of capillaries can be used, so that defects will be formed in one or more desired locations. The concepts as described herein may be extended to boules to control a radial distribution of defects from impurities and microvoids.

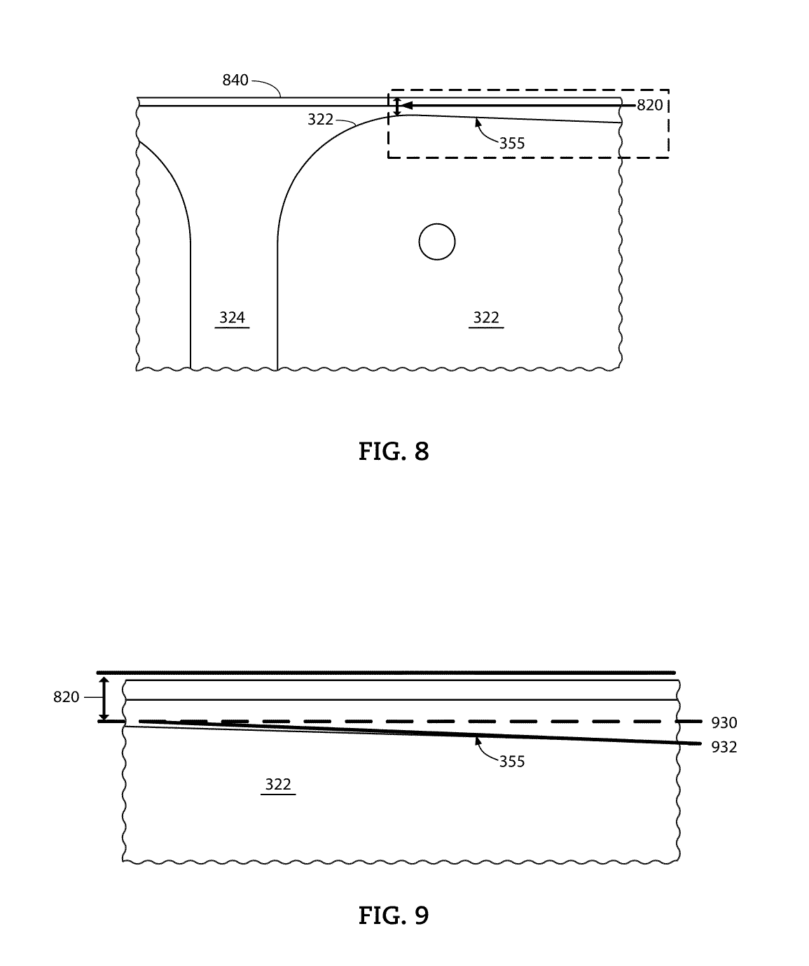

FIG. 8 includes an enlarged view to help further improve understanding of the effect of the slope of the spacers 322 on the melt flow during crystal growth. While much of the description with respect to FIG. 8 is directed to the embodiment as illustrated in FIGS. 3 to 6, the concepts also apply to other embodiments, such as the embodiment as illustrated in FIG. 7. In the embodiment as illustrated in FIG. 8, the velocity of the transverse flow of the melt is affected not only by the size and location of the capillaries, it can also affected by the distance 820 between the solid/liquid interface 840 and the top surface of the spacers 322. The die tip channel 355, which is above the spacer 322, restricts the melt to flow toward the outer edges of the die tip channel 355 and the die opening. Because the melt is continuously replenished as the melt material crystalizes at the solid/liquid interface, the flow of melt material continues throughout the crystal growth process.

FIG. 9 includes an enlarged portion of the die of the dashed box as illustrated in FIG. 8. In FIGS. 8 and 9, the upper surface of the spacers can be formed and mounted so that the upper surfaces of the spacer slope downwardly, away from the one or more capillaries. Thus, the velocity of the transverse flow within the die tip channel adjacent to the one or more capillaries toward the edges of the die tip channel can be further increased by using gravity to help the flow of the melt along the slope away from the capillary. In particular, the upper surface of the spacer can have a slope of at least 2%. FIG. 9 is an enlarged view of the sloping top surface of the spacer. Dashed line 930 shows the position of a horizontal line that is substantially parallel to the solid/liquid interface. Line 932 is an extension of the upper surface of the spacer 322. As illustrated in FIG. 9, the upper surface of the spacer 322 has a slope of approximately 2% from horizontal.

The dimensions of the die tip channel and die opening can have a significant impact upon crystal growth. The dimensions include the length of the die opening, the total fraction of the length occupied by the one or more capillaries, the elevational difference between the uppermost points along the die tips and the uppermost points along the spacers, the width of the die opening, which generally corresponds to the thickness of the spacers, and the shape of upper surface of the spacers. The shape of the upper surface of the die tips is described above.

In particular embodiments, a total length of the one or more capillaries for the die opening is no more than approximately 40%, no more than approximately 30%, or to no more than approximately 20% of the length of the die opening. Even more particularly, the total length of the one or more capillaries is no more than approximately 5% of the length of the die opening. In FIG. 3, the length of the capillary 324 corresponds to the total length of the one or more capillaries, and in FIG. 7, the sum of the lengths of the two capillaries 724 is the total length of the one or more capillaries. After reading this specification, skilled artisans will appreciate that the total length of the spacers 322 in FIG. 3 and the length of the spacer 722 in FIG. 7 is at least approximately 60%, approximately 70%, approximately 80%, or even approximately 95% of the length of the die opening 350.

Alternatively, area may be used instead of length. The area is determined from a top view of the die. In particular embodiments, a total area occupied by the one or more capillaries for the die opening is no more than approximately 40%, no more than approximately 30%, or to no more than approximately 20% of the area of the die tip channel. Even more particularly, the total area of the one or more capillaries is no more than approximately 5% of the area of the die tip channel. In FIG. 3, the area occupied by the capillary 324 corresponds to the total occupied by the one or more capillaries, and in FIG. 7, the sum of the areas occupied by the two capillaries 724 is the total area occupied by the one or more capillaries. After reading this specification, skilled artisans will appreciate that the total area occupied by the spacers 322 in FIG. 3 and the area occupied by the spacer 722 in FIG. 7 is at least approximately 60%, approximately 70%, approximately 80%, or even approximately 95% of the length of the die tip channel 355.

Some elevational differences between the uppermost points along the die tips and spacers have been previously described. For a given die opening width, the flow of melt can be too constricted if the elevation difference is too low. In such a situation, the melt (and thus the crystal) will not fill the entire die tip channel, and the crystal ribbon will not have a width corresponding to the length of the die opening. If the elevational difference is too large, the melt flow within die tip channel may be too low, and defects will be formed along a greater more of the solidification front, which means a higher defect density at a location farther from the one or more capillaries.

The thicknesses of the spacers affect and are generally the same as the thickness of the crystal ribbon being formed. The thickness is typically determined for the particular application for which the crystal sheet is intended, and thus, may be determined by a customer. Still, the thicknesses of the spacers affect the width of the die tip channel. In an embodiment, the spacers may have a thickness of at least 0.25 cm, at least 0.50, cm, or at least 0.75 cm, and in another embodiment, the spacers may have a thickness no greater than 1.5 cm, no greater than 1.4 cm, or no greater than 1.3 cm. In other embodiments, the spacers may have a thickness that is thinner or thicker than the particular thicknesses described. For example, as wider sapphire ribbons can be realized, the thickness of such sapphire ribbons may be increased to provide sufficient mechanical support for the sapphire ribbon.

As previously described, and upper surface of the spacer may be sloped at least 2° from a horizontal plane. In another embodiment, the slope can be at least 4°, 6°, or 8°. If the slope is too large, the change in velocity of the melt as a function of length of the die opening may become too large meaning that the melt will be more stagnant closer to the capillary and allow defects, such as microvoids and impurities, to be at a higher concentration at a location closer to the one or more capillaries. Thus, the slope may be no greater than 45°, no greater than 30°, or no greater than 20°.

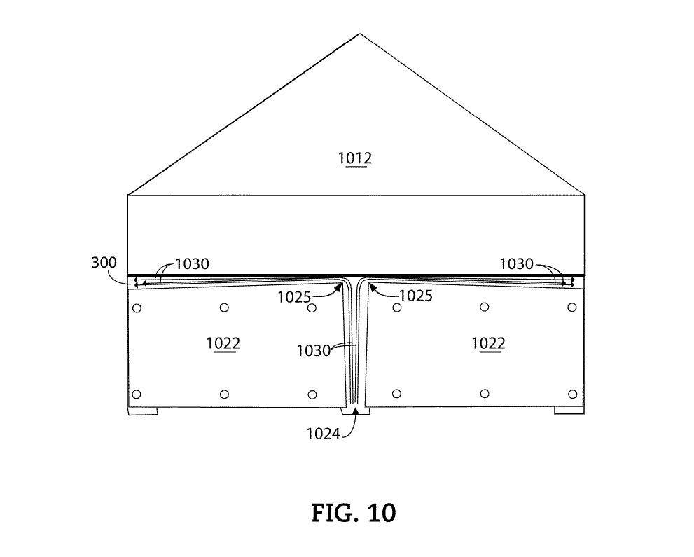

In the embodiment of FIG. 4, the inner corner of each of the spacers 322 (toward the capillary 324) is significantly rounded and may result in some degree of flow stagnation above the capillary 324. Such stagnation of the melt flow can result in microvoids and impurities being deposited in the center of the crystal ribbon due to the lack of sufficient transverse flow. Accordingly, where it is undesirable to have defects in the central portion of the crystal ribbon, the spacers may have sharper corners at the top of the capillary, such as those illustrated in FIG. 10, to reduce pooling and stagnation at the top of the capillary. Similar to FIG. 6, the front die plate is removed from the illustration to improve understanding of the features of the embodiment illustrated in FIG. 10. The spacers 1022 have relatively sharp corners 1025 adjacent to the capillary 1024. The flow is illustrated by arrows 1030. Stagnation above the capillary 1024 may be reduced as compared to the capillary 324, and thus, the crystal ribbon 1012 produced by the die may have a lower likelihood of forming defects within a central band of the crystal ribbon 1012.

The level of melt in the crucible can have a significant factor in the percentage of microvoids and impurities that are moved in the direction of the melt flow. A lower melt level tends to reduce the velocity of the flow up through the one or more capillaries and results in more microvoids and impurities distributed more of the primary surfaces rather than concentrated at the outer edges. The particular values for acceptable levels of melt within the crucible may be depend on the size of the crucible, the number of dies, the geometries of capillaries, die tip channels, and die openings, and material of the melt. After reading this specification, skilled artisans will be able to determine or test to determine acceptable levels to be used.

With configurations as previously described, referring to FIG. 3, the velocity of the melt flowing within the die tip channel adjacent to the capillary 324 (“transverse velocity”) is greater than the velocity of the melt flowing vertically within the capillary 324 (“vertical velocity”), and referring to FIG. 7, the transverse velocity within the die tip channel adjacent to the capillaries 724 is greater than the vertical velocities within the capillaries 724. More particularly, the transverse velocity can be greater than the vertical velocity by a factor of at least 2. Even more particularly the transverse velocity can be greater than the vertical velocity by a factor of at least 10. For example, with a crystal pull rate of 2.5 cm/hr (1 in/hr) (which controls the vertical melt flow velocity), the transverse velocity can be greater than 2.5 cm/hr (1 in/hr), greater than 5 cm/hr (2 in/hr), or even greater than 25 cm/hr (10 in/hr).

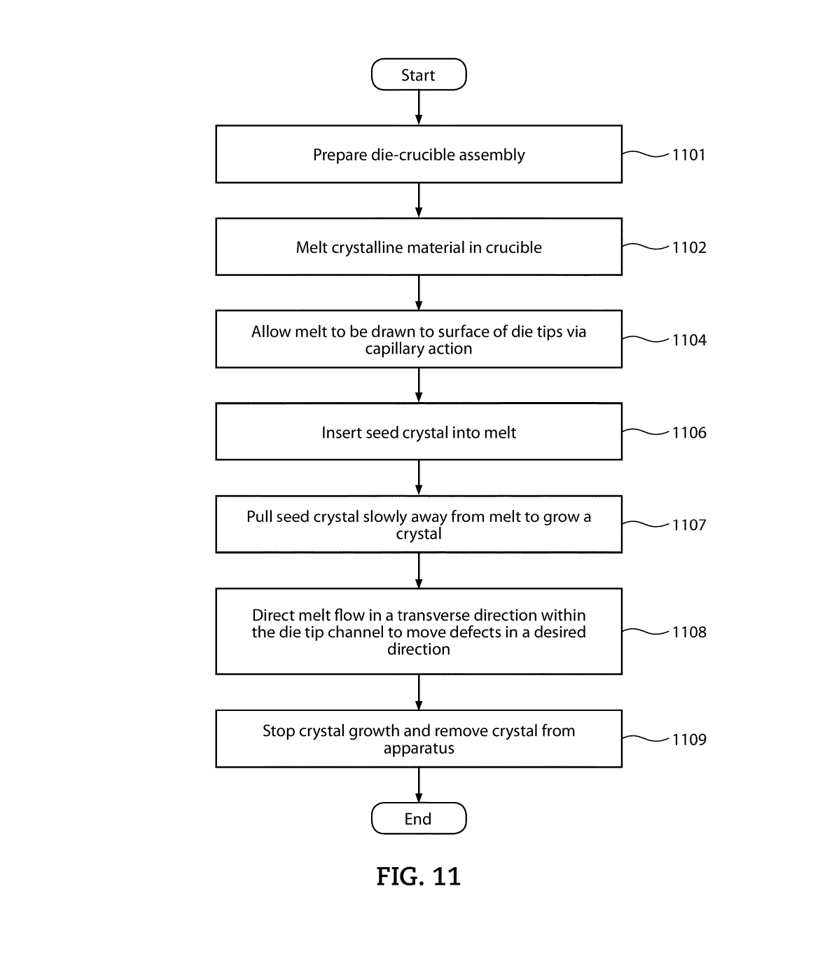

FIG. 11 includes a flowchart showing steps in a method of growing a crystal ribbon according to an exemplary, non-liming embodiment. In step 1101, a crucible-die assembly is prepared. The crucible adapted will contain a liquid melt, and a die is mounted partly within the crucible. The die has one or more capillaries extending from within the crucible to the die tip. In step 1102, a crystalline material is melted in the crucible to form the liquid melt. In step 1104, capillary action is used to draw liquid melt from the crucible through the one or more capillaries and onto the surface of the die tip. In step 1106, a crystal seed is inserted into the liquid melt on the surface of the die tip, and then in step 1107, the crystal seed is pulled away from the surface of the die tip to grow a crystal. In step 1108, as the seed is pulled away, the liquid melt flow in a transverse direction within the die tip channel at a sufficient velocity to move microvoids and impurities away from the one or more capillaries and toward a desired location within the crystal. After the crystal is formed, in step 1110, the growth process is stopped, and the crystal can be removed for further processing (such as trimming the edges to remove defects and separating the crystal ribbon into multiple substrate sections.) Using the methods, dies, and apparatus described above, a crystal ribbon that is at least 15 cm (6 inches) in width and of a desired length (for example a length greater than 15 cm (6 inches)) can be produced that are substantially free of defects, such as microvoids and relatively high impurity concentrations.

Impurities, such as calcium particles, are believed to be associated with the formation of microvoids. With respect to the embodiment as illustrated in FIGS. 3 to 6, a relatively higher transverse velocity of the melt within the die tip channel 355 adjacent to the capillary 324 can help to form a large majority of the defects, such as microvoids and impurities, along the outer edges of the crystal ribbon. Because such defects are concentrated along the outer edges of the crystal ribbon, rather than distributed across the all of the primary surfaces of the crystal ribbon, these defects can be easily removed by removing the outer edges of the crystal ribbon or avoided by cutting particular substrates, such as wafers, from the crystal ribbon at locations spaced apart from the outer edges. This clearly will provide a significant improvement in the production of high quality crystals when dies are used according to embodiments as described herein. The ability to control the location of impurities provides multiple benefits: higher growth rates are possible, growth will be less sensitive to impurity variation between different lots of feed material, and control of growth in directions normal to the growth direction can be obtained by varying the dimensions of the flow path.

Although much of the previous discussion is directed at the production of crystal ribbons, embodiments can also be used in the production of different shaped crystals where it is desirable to direct defects, such as microvoids and relatively higher impurity concentrations, to a particular part of the crystal body by causing transverse melt flow in that direction. The concepts can be extended to other geometries that use directional solidification, including shaped crystals that are cylindrical, flat (edge defined), etc. The concepts as described herein are also not limited to edge-defined growth methods and could be applied, for example, to the use of a conical crucible lid with a central capillary in cylindrical Czochralski growth. Although much of the discussion herein refers to the growth of sapphire crystals, the concepts could also be applied to directional solidification of metals, metal alloys, crystal and amorphous semiconductors, etc., in arbitrary geometries. The concepts described herein can be extended to produce substantially scratch-resistant materials such as windows, cover for cell phones or other mobile device, etc. that are substantially free of microvoids and have low impurity concentrations.

Many different aspects and embodiments are possible. Some of those aspects and embodiments are described herein. After reading this specification, skilled artisans will appreciate that those aspects and embodiments are only illustrative and do not limit the scope of the present invention. Embodiments may be in accordance with any one or more of the items listed below.

Item 1. An apparatus for growing a ribbon of crystal includes a crucible adapted to contain a liquid melt, and a die located in the crucible. The die has die opening defined at least in part by a die tip configured to support a solid/liquid growth interface and to control a shape of the crystal. The die opening has a length that is greater than its width, wherein the die has one or more capillaries extending from within the crucible toward the die opening. A total length of the one or more capillaries is less than approximately 30% of a length of the die opening, such that a liquid melt drawn up through the one or more capillaries can flow along a bottom surface of a die tip channel away from the capillary in a direction parallel to a length of the die opening.

Item 2. The apparatus of Item 1, wherein the total length of the one or more capillaries is less than approximately 10% of the length of the die opening.

Item 3. The apparatus of any one of the preceding Items, wherein the die has only a single capillary extending toward the die opening.

Item 4. The apparatus of Item 3, wherein the single capillary is located substantially at a center of the length of the die.

Item 5. The apparatus of any one of Items 1 or 2, wherein the one or more capillaries include a plurality of capillaries, and wherein a total of lengths of the plurality of capillaries is less than approximately 20% of the length of the die opening.

Item 6. The apparatus of any one of Items 1, 2, or 5, wherein the one or more capillaries include at least two capillaries, one capillary adjacent to each end of the die tip channel.

Item 7. The apparatus of any one of the preceding Items, wherein the die includes a pair of opposing plates that are generally rectangular in shape and are separated by at least one spacer.

Item 8. The apparatus of Item 7, wherein a bottom of the die tip channel includes an upper surface of the at least one spacer.

Item 9. The apparatus of Item 7, wherein a bottom of the die tip channel includes an upper surface of the at least one spacer, and wherein the at least one spacer is mounted between the plates so that the upper surface of the at least one spacer is lower than tops of the opposing plates.

Item 10. The apparatus of Item 9, wherein the die includes a pair of opposing plates have a rectangular shape.

Item 11. The apparatus of Item 7, wherein the pair of opposing plates are separated by at least two spacers mounted between the plates so that a capillary of the one or more capillaries is at least partly defined by a gap between the two spacers.

Item 12. The apparatus of any one of the preceding Items, wherein from a cross-sectional view along a width of the die, the die tip is rectangular, sloped, or curved.

Item 13. The apparatus of any one of the preceding Items, wherein the apparatus is configured to grow the ribbon of crystal by edge-defined film-fed growth.

Item 14. The apparatus of any one of the preceding Items, wherein the die includes a pair of opposing rectangular shaped plates separated by at least one spacer, and wherein the at least one spacer has a thickness of at least 0.075 cm (0.03 inches).

Item 15. The apparatus of any one of the preceding Items, wherein the total length of the one or more capillaries is sufficiently less than the length of the die opening to produce a melt flow at a velocity within the die tip channel at a location adjacent to the capillary that is greater than a velocity of the melt flow through the one or more capillaries.

Item 16. The apparatus of Item 15, wherein the velocity of the melt within the die tip channel is greater than the velocity of the melt through the one or more capillaries by at least a factor of 2.

Item 17. The apparatus of Item 15, wherein the velocity of the melt within the die tip channel is greater than the velocity of the melt through the one or more capillaries by at least a factor of 10.

Item 18. The apparatus of any one of the preceding Items, wherein the apparatus includes a plurality of dies are arranged side-by-side so that a plurality of crystals can be grown simultaneously.

Item 19. The apparatus of Item 18, wherein for two immediately adjacent dies, openings of the die tips are no closer than approximately 0.22 cm (0.085 inches).

Item 20. The apparatus of any one of the preceding Items, wherein the bottom surface of the die tip channel is sloped to produce a gravity-driven flow of the liquid melt at a velocity sufficient to carry impurities in the liquid melt to a desired location along the die tip channel so that the impurities can be deposited at a corresponding desired location in the ribbon of crystal grown using the die.

Item 21. The apparatus of Item 20, wherein the one or more capillaries includes a plurality of capillaries located adjacent to outer edges of the die tip channel, and wherein the bottom surface of the die tip channel is sloped so that, when the ribbon of crystal is grown using the die, the liquid melt can flow inward to deposit the impurities in the crystal along a central band of the ribbon of crystal.

Item 22. The apparatus of Item 20, wherein the one or more capillaries includes a particular capillary is located away from an outer edge of the die tip channel, wherein the bottom surface of the die tip channel is downwardly sloped away from the particular capillary so that, when the ribbon of crystal is grown using the die, the liquid melt can flow toward the outer edge of the die tip channel at a velocity sufficient to carry impurities toward the outer edge of the die tip channel and deposit the impurities at an outer edge of the ribbon of crystal.

Item 23. The apparatus of Item 22, wherein the one or more capillaries includes a only one capillary, and wherein from a top view, the capillary is located within a center the die opening, and wherein the bottom surface of the die tip channel is downwardly sloped away from the single capillary toward the outer edges of the die tip channel.

Item 24. The apparatus of Item 20, wherein bottom surface of the die tip channel has a downward slope along the length of the die opening from a capillary of the one or more capillaries to an outer edge of the die tip channel.

Item 25. The apparatus of Item 4, wherein the bottom surface of the die tip channel has a downward slope away from the one or more capillaries toward the outside edge of the die tip channel so that liquid melt drawn up through the one or more capillaries can flow down the slope away from the one or more capillaries.

Item 26. The apparatus of Item 9, wherein the upper surface of the spacer has a downward slope away from a capillary of the one or more capillaries.

Item 27. The apparatus of any one of Items 20 to 26, wherein the bottom surface of the die tip channel has an elevational difference of at least 0.075 cm (0.03 inches) between a highest point on the bottom surface and a lowest point on the bottom surface.

Item 28. The apparatus of any one of Items 20 to 27, wherein the bottom surface of the die tip channel has a slope of at least 2 percent.

Item 29. The apparatus of Item 26, wherein an elevational difference between an uppermost point along one of the opposing die plates and a highest point along the upper surface of the spacer is at least 0.11 cm (0.043 inches).

Item 30. The apparatus of Item 26, wherein an elevational difference between an uppermost point along one of the opposing die plates and a highest point along the upper surface of the spacer is at least 0.13 cm (0.05 inches).

Item 31. The apparatus of Item 26, wherein an elevational difference between an uppermost point along one of the opposing die plates and a highest point along the upper surface of the spacer is at least 0.19 cm (0.075 inches).

Item 32. The apparatus of Item 27, wherein a position of the spacer can be adjusted to change a slope of the upper surface of the spacer, an elevational difference between an uppermost point along one of the opposing die plates and a highest point along the upper surface of the spacer, or both the slope and the elevational difference.

Item 33. The apparatus of any one of the preceding Items, wherein the die can produce a melt flow at a velocity within the die tip channel that is greater than approximately 2.5 cm/hr (1 in/hr), greater than approximately 5 cm/hr (2 in/hr), or greater than approximately 25 cm/hr (10 in/hr).

Item 34. A die can be used in growing a crystal from a liquid melt. The die includes a die tip to support a solid/liquid growth interface and control a shape of the crystal, wherein the die tip at lease partly defines a die opening and a die tip channel; a lower die portion to be immersed in a liquid melt contained in a crucible; and one or more capillaries extending from the lower die portion to the die tip channel to supply the liquid melt to a top surface of the die tip. From a top view, a total area occupied by the one or more capillaries coupled to the die tip channel is less than 30% of an area of the die tip channel.

Item 35. The die of Item 34, wherein the total area occupied by the one or more capillaries is less than 10% of the area of the die tip channel.

Item 36. The die of any one of Items 34 or 35, wherein the die includes only a single capillary.

Item 37. The die of Item 36, wherein the single capillary is located substantially in a center of the length of the die opening.

Item 38. The die of any one of Items 34 to 36, wherein a total length of the one or more capillaries is sufficiently less than a length of the die opening to produce a velocity of the melt flow within die tip channel that is greater than a velocity of the melt flow through the one or more capillaries.

Item 39. The die of Item 38, wherein the velocity of the melt flow within die tip channel is greater than the velocity of the melt flow through the one or more capillaries by at least a factor of 2.

Item 40. The die of Item 38, the velocity of the melt flow within die tip channel is greater than the velocity of the melt flow through the one or more capillaries by at least a factor of 10.

Item 41. The die of Item 38, wherein the velocity of the melt flow within die tip channel is greater than approximately 2.5 cm/hr (1 in/hr), greater than approximately 5 cm/hr (2 in/hr), or greater than approximately 25 cm/hr (10 in/hr).

Item 42. The die of any one of Items 34 to 41, wherein the bottom surface of the die tip channel is sloped to produce a gravity-driven flow of the liquid melt at a velocity sufficient to carry impurities in the liquid melt to a desired location along the die tip channel so that the impurities can be deposited at a corresponding desired location in a crystal grown using the die.

Item 43. The die of any one of Items 34 to 41, wherein the one or more capillaries includes a plurality of capillaries located adjacent to outer edges of the die tip channel and wherein the bottom surface of the die tip channel is sloped so that, when the crystal is grown using the die, the liquid melt can flow toward a center of the dip tip channel to deposit the impurities in the crystal along a central band of the crystal.

Item 44. The die of any one of Items 34 to 41, wherein the one or more capillaries includes a particular capillary located away from an outer edge of the die tip channel, wherein the bottom surface of the die tip channel is downwardly sloped away from the particular capillary so that, when the crystal is grown using the die, the liquid melt can flow toward the outer edge of the die tip channel at a velocity sufficient to carry impurities toward the outer edge of the die tip channel and deposit the impurities at an outer edge of the crystal.

Item 45. A method of growing a crystal includes providing a crucible adapted to contain a liquid melt, and providing a die located in the crucible, the die having an die tip to support a solid/liquid growth interface and control the shape of the crystal material and having one or more capillaries extending from within the crucible toward the die opening. The method further includes melting a quantity of crystalline material in the crucible to form the liquid melt, using capillary action to draw the liquid melt within the crucible through the one or more capillaries and onto the surface of the die tip, and inserting a crystal seed into the liquid melt adjacent to the surface of the die tip and then pulling the seed away from the surface of the die tip at a rate to grow the crystal. As the seed is pulled away, a flow in the liquid melt within a die tip channel is directed so that the flow of the liquid melt stagnates at a desired location within the die tip channel with respect to the crystal so that impurities resulting from crystal growth are more concentrated at a desired location within the crystal.

Item 46. The method of Item 45, wherein the crystal is grown by edge-defined film-fed growth.

Item 47. The method of Item 45, wherein the crystal is grown as a boule.

Item 48. The method of Item 45, further including removing portions of the crystal containing the impurities.

Item 49. The method of any one of Items 45 to 48, wherein the crystal includes sapphire.

Item 50. The method of any one of Items 45 to 49, wherein the impurities include microvoids formed during crystal growth.

Item 51. The method of any one of Items 45 to 50, wherein a velocity of the liquid melt flowing within the die tip channel is greater than a velocity of the liquid melt flowing through the one or more capillaries.

Item 52. The method of Item 51, wherein the velocity of the liquid melt flowing within the die tip channel is greater than the velocity of the liquid melt flowing through the one or more capillaries by at least a factor of 2.

Item 53. The method of Item 51, wherein the velocity of the liquid melt flowing within the die tip channel is greater than the velocity of the liquid melt flowing through the one or more capillaries by at least a factor of 10.

Item 54. The method of any one of Items 45 to 53, wherein the bottom surface of the die tip channel is sloped to produce a gravity-driven flow of the liquid melt at a velocity sufficient to carry impurities in the liquid melt to the desired location within the die tip channel so that impurities are deposited at the desired location within the crystal.

Item 55. The method of Item 53, wherein the one or more capillaries includes a particular capillary is located away from an outer edge of the die tip channel, wherein the bottom surface of the die tip channel is downwardly sloped away from the particular capillary so that, when the crystal is grown using the die, the liquid melt can flow toward the outer edge of the die tip channel at a velocity sufficient to carry impurities toward the outer edge of the die tip channel and deposit the impurities at an outer edge of the crystal.

Item 56. A crystalline material that is substantially free of microvoid defects produced by the method of any one of Items 45 to 53.

Item 57. The crystalline material of Item 56, wherein the crystal includes a sapphire wafer.

Item 58. The crystalline material of Item 56, wherein the crystal includes a scratch-resistant material, a window, or a cover for a cell phone or other mobile device.

### EXAMPLES

The concepts described herein will be further described in the following examples, which do not limit the scope of the invention described in the claims. Specific sized crystals were grown to show the viability of the concepts described herein. Clearly, different sizes of crystals can be formed, and the apparatuses, dies, and crystals are not limited to the geometries described with respect to the Examples.

Crystals were grown using a variety of dies, each having a different minimum channel size. The die plates in this experiment were each approximately 16 cm (6.25 inches) in length, as measured in the direction of the die opening, to form single crystal sapphire ribbons that can be subsequently processed to form 15 cm (6-inch) nominal sapphire substrate disks. The die plates were separated by spacers that were sized and mounted to create a single central capillary between the adjacent die plates, as illustrated in FIG. 6.

For each of the five die assemblies, the thickness of the spacers (and thus the space between the die plates) was 0.075 cm (0.030 inches). Each of the spacers (used between the die plates) was approximately 7.5 cm (3 inches) in length, as measured in the direction of the length of the die opening, leaving a central capillary that was approximately 0.63 cm (0.25 inches) in length and 0.075 cm (0.030 inches) in width. The spacers have upper surfaces that were sloped.

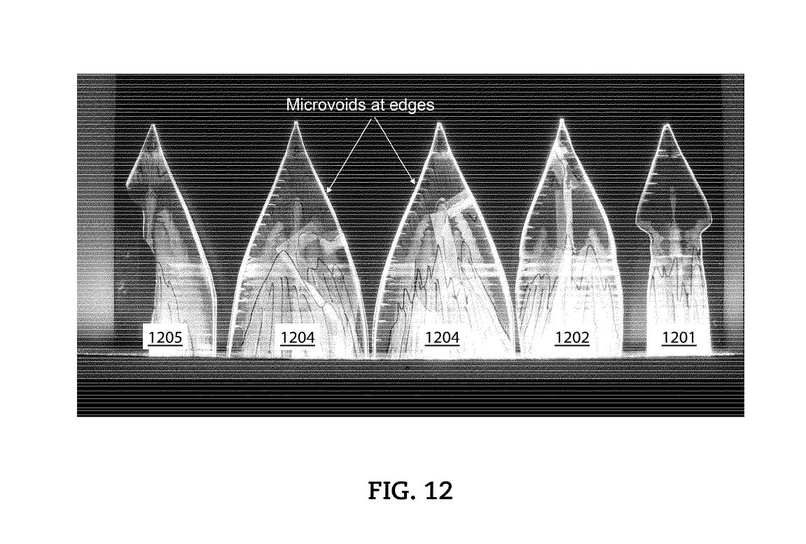

For each die assembly, the elevational difference between the uppermost points of the die tips and the uppermost points along the upper surfaces of the spacers, which corresponds to the minimum depth of die tip channel, was varied. FIG. 12 includes a picture of actual crystal ribbons grown experimentally. Crystals 1201 and 1202 were grown using die assemblies with an elevational difference between uppermost points of the die tips and the uppermost points of the spacers of 0.11 cm (0.043 inches), crystal 1203 was grown using a die assembly with an elevational difference of 0.16 cm (0.060 inches), crystal 1204 was grown using a die assembly with an elevational difference of 0.22 cm (0.085 inches), and crystal 1205 was grown using a die assembly with and elevational difference of (0.19 cm (0.073 inches). FIG. 12 also illustrates that microvoids (illustrated by the bright white lines at the edges of the crystals) are located at the outer edges of the crystals.

Crystals 1201 and 1202 did not spread all the way across the die. The other crystals (1203 to 1205) were all spread full width (crystal 1205 was broken before the picture was taken, it was also full width). Accordingly, it appears that, for a sapphire crystal grown using this type and size of center capillary die, an elevational difference of 0.11 cm (0.043 inches) is too small for full-width crystal growth for the particular geometries selected for the crystal ribbon. However, if other geometries were changed, such as the width of the spacers, the full width may be achieved for an elevational difference of 0.11 cm (0.043 inches), but the thickness of the crystal ribbon may be affected. Alternatively, a smaller die opening may be used with such a relatively low elevational difference.

Note that not all of the activities described above in the general description or the examples are required, that a portion of a specific activity may not be required, and that one or more further activities may be performed in addition to those described. Still further, the order in which activities are listed is not necessarily the order in which they are performed.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

The specification and illustrations of the embodiments described herein are intended to provide a general understanding of the structure of the various embodiments. The specification and illustrations are not intended to serve as an exhaustive and comprehensive description of all of the elements and features of apparatus and systems that use the structures or methods described herein. Certain features, that are for clarity, described herein in the context of separate embodiments, may also be provided in combination in a single embodiment. Conversely, various features that are, for brevity, described in the context of a single embodiment, may also be provided separately or in a subcombination. Further, reference to values stated in ranges includes each and every value within that range. Many other embodiments may be apparent to skilled artisans only after reading this specification. Other embodiments may be used and derived from the disclosure, such that a structural substitution, logical substitution, or another change may be made without departing from the scope of the disclosure. Accordingly, the disclosure is to be regarded as illustrative rather than restrictive.

What is claimed is:

1. A method of growing a crystal comprising:
providing a crucible adapted to contain a liquid melt;
providing a die located in the crucible, the die having an die tip to support a solid/liquid growth interface and control the shape of the crystal material and having one or more capillaries extending from within the crucible toward the die opening;
melting a quantity of crystalline material in the crucible to form the liquid melt;
using capillary action to draw the liquid melt within the crucible through the one or more capillaries and onto the surface of the die tip;
inserting a crystal seed into the liquid melt adjacent to the surface of the die tip and then pulling the seed away from the surface of the die tip at a rate to grow the crystal; and
as the seed is pulled away, directing a flow in the liquid melt within a die tip channel so that the flow of the liquid melt stagnates at a desired location within the die tip channel with respect to the crystal so that impurities resulting from crystal growth are more concentrated at a desired location within the crystal.

2. The method of claim 1, wherein the crystal is grown by edge-defined film-fed growth.

3. The method of claim 1, further comprising removing portions of the crystal containing the impurities.

4. The method of claim 1, wherein the crystal comprises sapphire.

5. The method of claim 1, wherein the impurities include microvoids formed during crystal growth.

6. The method of claim 1, wherein a velocity of the liquid melt flowing within the die tip channel is greater than a velocity of the liquid melt flowing through the one or more capillaries.

7. The method of claim 1, wherein a bottom surface of the die tip channel is sloped to produce a gravity-driven flow of the liquid melt at a velocity sufficient to carry impurities in the liquid melt to the desired location within the die tip channel so that impurities are deposited at the desired location within the crystal.

8. The method of claim 1, wherein the one or more capillaries comprises a particular capillary is located away from an outer edge of the die tip channel, wherein a bottom surface of the die tip channel is downwardly sloped away from the particular capillary so that, when the crystal is grown using the die, the liquid melt can flow toward the outer edge of the die tip channel at a velocity sufficient to carry impurities toward the outer edge of the die tip channel and deposit the impurities at an outer edge of the crystal.

9. A die for use in growing a crystal from a liquid melt, the die comprising:
a die tip to support a solid/liquid growth interface and control a shape of the crystal, the die tip at lease partly defining a die opening and a die tip channel;
a lower die portion to be immersed in a liquid melt contained in a crucible; and
one or more capillaries extending from the lower die portion to the die tip channel to supply the liquid melt to a top surface of the die tip,
wherein from a top view, a total area or a total area occupied by the one or more capillaries coupled to the die tip channel is less than 30% of a length or an area of the die tip channel.

10. The die of claim 9, wherein the total length occupied by the one or more capillaries is less than 10% of the area of the die tip channel.

11. The die of claim 9, wherein the total length occupied by the one or more capillaries is less than 10% of the area of the die tip channel.

12. The die of claim 9, wherein the one or more capillaries is a single capillary located substantially in a center of the length of the die opening.

13. The die of claim 9, wherein a total length of the one or more capillaries is sufficiently less than a length of the die opening to produce a velocity of the melt flow within die tip channel that is greater than a velocity of the melt flow through the one or more capillaries.

14. The die of claim 9, wherein a bottom surface of the die tip channel is sloped to produce a gravity-driven flow of the liquid melt at a velocity sufficient to carry impurities in the liquid melt to a desired location along the die tip channel so that the impurities can be deposited at a corresponding desired location in a crystal grown using the die.

15. The die of claim 9, wherein the one or more capillaries comprise a plurality of capillaries, and wherein a total of lengths or total areas of the plurality of capillaries is less than approximately 20% of the length or area of the die opening.

16. The die of claim 9, wherein the die comprises a pair of opposing plates that are generally rectangular in shape and are separated by at least one spacer.

17. The die of claim 9, wherein the die comprises a pair of opposing rectangular shaped plates separated by at least one spacer, and wherein the at least one spacer has a thickness of at least 0.075 cm (0.03 inches).

18. The die of claim 9, wherein the one or more capillaries comprises a particular capillary is located away from an outer edge of the die tip channel, wherein a bottom surface of the die tip channel is downwardly sloped away from the particular capillary so that, when the ribbon of crystal is grown using the die, the liquid melt can flow toward the outer edge of the die tip channel at a velocity sufficient to carry impurities toward the outer edge of the die tip channel and deposit the impurities at an outer edge of the ribbon of crystal.

19. The die of claim 9, wherein a bottom surface of the die tip channel has a slope of at least 2 percent.

20. An apparatus for growing a ribbon of crystal, the apparatus comprising:
a crucible adapted to contain a liquid melt; and
a die located in the crucible, the die having die opening defined at least in part by a die tip configured to support a solid/liquid growth interface and to control a shape of the crystal, and the die opening having a length that is greater than its width, wherein the die has one or more capillaries extending from within the crucible toward the die opening,
wherein a total length of the one or more capillaries is less than approximately 30% of a length of the die opening, such that a liquid melt drawn up through the one or more capillaries can flow along a bottom surface of a die tip channel away from the capillary in a direction parallel to a length of the die opening.
